(19) United States
(12) Patent Application Publication
(10) Pub. No.: US 2006/0213615 A1
(43) Pub. Date: Sep. 28, 2006

(54) Laser nozzle cleaning tool

(75) Inventor: Abbas Rastegar, Schenectady, NY (US)

Correspondence Address: FULBRIGHT & JAWORSKI L.L.P., 600 CONGRESS AVE., SUITE 2400, AUSTIN, TX, 78701, US

(73) Assignee: SEMATECH, Inc.

(21) Appl. No.: 11/305,312

(22) Filed: Dec. 16, 2005

Related U.S. Application Data
(60) Provisional application No. 60/636,829, filed on Dec. 16, 2004.
(60) Provisional application No. 60/636,827, filed on Dec. 16, 2004.

(51) Int. Cl. H01L 21/306

(52) U.S. Cl. 156/345.5

(57) ABSTRACT

An apparatus including a laser operating in different cleaning techniques is provided. In one embodiment, the laser interacts with the particle to remove the particle by expansion. In another embodiment, a liquid-assisted laser cleaning technique evaporates a liquid layer on the surface by laser pulses and subsequently removing the particles from the surface. Further, the present disclosure provides parameters to control the energy transfer to the particle. For example, for a shock wave generation parameters, the droplets size and concentration (e.g., pressure), substrate surface temperature, chemical composition of the droplets may be controlled.

This application claims priority to, and incorporates by reference, U.S. Provisional Patent Application Ser. Nos. 60/636,829 and 60/636,827, which were filed on Dec. 16, 2004.

### BACKGROUND OF THE INVENTION

1. Field of the Invention

The present invention relates generally to semiconductor fabrication processes, and more particularly to an apparatus and method for removing particles from a surface.

2. Description of Related Art

Removal of sub-100 nanometer (nm) particles from a surface can be a challenging subject for semiconductor fabrication processes. These particles may include contaminants on the surface including materials such as organic material, dust, residue, and metal impurities. Generally, the particles accumulate when the substrate is being stored or is in a stand-by state between successive processes and may cause defects, particularly for integrated circuits on a substrate.

The surface-particle interactions depend on the material and the surface structure. As such, the energy transfer efficiency needed to remove a particle from a surface strongly depends on the size of the particle on the surface. Generally, adhesive forces between the particle and the surface need to be broken and the particle needs to be transported far enough away from the surface such that the particle will not be redeposited on the surface.

Current methods for removing particles include wet cleaning techniques that involve immersing a substrate in a series of chemical solutions or spraying a series of chemical solutions onto a substrate, including for example, hydrofluoric acid, hydrogen peroxide solution, sulfuric acid, etc. In some techniques, a spin brush and/or a megasonic cleaner may be included. However, these processes are both expensive and produce waste that is environmentally harmful. Additionally, the use of a spin brush or an megasonic cleaner can be effective in removing large particles, but are hardly effective in removing particles on the order of submicrons or smaller.

Additionally, Next Generation Lithography (NGL) used in semiconductor technology includes reflective optics on glass substrates which have a surface roughness of approximately 1.5 Angstrom RMS or less to prevent scattering of the light, which may degrade the lithography process performance. Generally, all particles larger than about 27 nanometers need to be removed from the surface of a mask substrate that is used for NGL. The conventional wet cleaning techniques that use under etching of particles to remove particles from the surface are no longer applicable as they increase the surface roughness beyond the required value. In addition, most of the current advanced cleaning tools do not have the ability to remove the total particles with size of 27 nm and larger from the surface of the plates. This is due lack of a mechanism that be able to convey relatively high energy or momentum in distances of few nanometers from the surface. Additionally, current tools lack a mechanism to increase the population of reactive species in the vicinity of interface. Most of the chemical reactions are driven by diffusion process of the reactive species toward the surface.

Laser shock wave cleaning is another application using laser for surface cleaning. Particle removal efficiency depends on the momentum transferred to the particle on the surface, which in turn depends on the shock velocity parallel to the surface. The shock velocity depends on different parameters including the gas temperature and pressure. During the shock creation, plasma will form around the focus point of the laser light. However, when the focal point of the laser comes close to the surface, the plasma created can touch the surface and can cause damage to the surface.

The referenced shortcomings are not intended to be exhaustive, but rather are among many that tend to impair the effectiveness of previously known techniques concerning particle removal; however, those mentioned here are sufficient to demonstrate that the methodologies appearing in the art have not been satisfactory and that a significant need exists for the techniques described and claimed in this disclosure.

### SUMMARY OF THE INVENTION

For sub 100 nm particles, physical techniques in addition to chemical techniques may be used to separate particles from a surface. Different laser cleaning techniques, such as using a laser interaction with the particle or a liquid-assisted laser cleaning technique may use sudden evaporation of a liquid (e.g., water) on the surface by laser pulses to remove particles from the surface. Further, the present disclosure provides parameters to control the energy transfer to the particle. For example, for the shock wave generation parameters, the droplets size and concentration (e.g., pressure), substrate surface temperature, chemical composition of the droplets may be controlled.

The term “coupled” is defined as connected, although not necessarily directly, and not necessarily mechanically.

The terms “a” and “an” are defined as one or more unless this disclosure explicitly requires otherwise.

The term “substantially,” “about,” and its variations are defined as being largely but not necessarily wholly what is specified as understood by one of ordinary skill in the art, and in one-non and in one non-limiting embodiment the substantially refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1A is side-view of a cleaning tool, in accordance with embodiments of this disclosure.

FIG. 1B is a top-view of the cleaning tool, in accordance with embodiments of this disclosure.

FIG. 2 is a laser nozzle, in accordance with embodiments of this disclosure.

FIG. 3 is a plasma chamber cap for a laser nozzle, in accordance with embodiments of this disclosure.

FIG. 4 shows confinement of plasma by a magnetic field, in accordance with embodiments of this disclosure.

FIGS. 5A and 5B show an azimuthal magnetic field by use of torrid, in accordance with embodiments of this disclosure.

FIGS. 6A and 6B show an electric field for confining plasma in accordance with embodiments of this disclosure.

FIG. 7 shows of a vapor/fume cleaning technique, in accordance with embodiments of this disclosure.

FIG. 8 shows a laser nozzle coupled to a laser, in accordance with embodiments of this disclosure.

FIG. 9 shows a horizontal configuration of the laser nozzle and laser of FIG. 8, in accordance with embodiments of this disclosure.

FIG. 10 shows a laser coupled to long focal lens, in accordance with embodiments of this disclosure.

### DESCRIPTION OF ILLUSTRATIVE EMBODIMENTS

The invention and the various features and advantageous details are explained more fully with reference to the nonlimiting embodiments that are illustrated in the accompanying drawings and detailed in the following description. Descriptions of well known starting materials, processing techniques, components and equipment are omitted so as not to unnecessarily obscure the invention in detail. It should be understood, however, that the detailed description and the specific examples, while indicating embodiments of the invention, are given by way of illustration only and not by way of limitation. Various substitutions, modifications, additions, and/or rearrangements within the spirit and/or scope of the underlying inventive concept will become apparent to those skilled in the art from this disclosure.

The present disclosure provides integrating different laser-based cleaning methods with a wet bench approach to control and/or substantially eliminate damage to a surface during a particle removal process. In one embodiment, shockwaves may be created in the vapor/air environment, which is more effective than the conventional techniques where shockwaves are created in a liquid medium. In the latter case, most of the shock wave energy is absorbed in the liquid environment and therefore, very little energy will be exerted to the contaminant particle. The cleaning tool and methods for creating shockwaves of the present disclosure allow energy loss in vapor to be minimized.

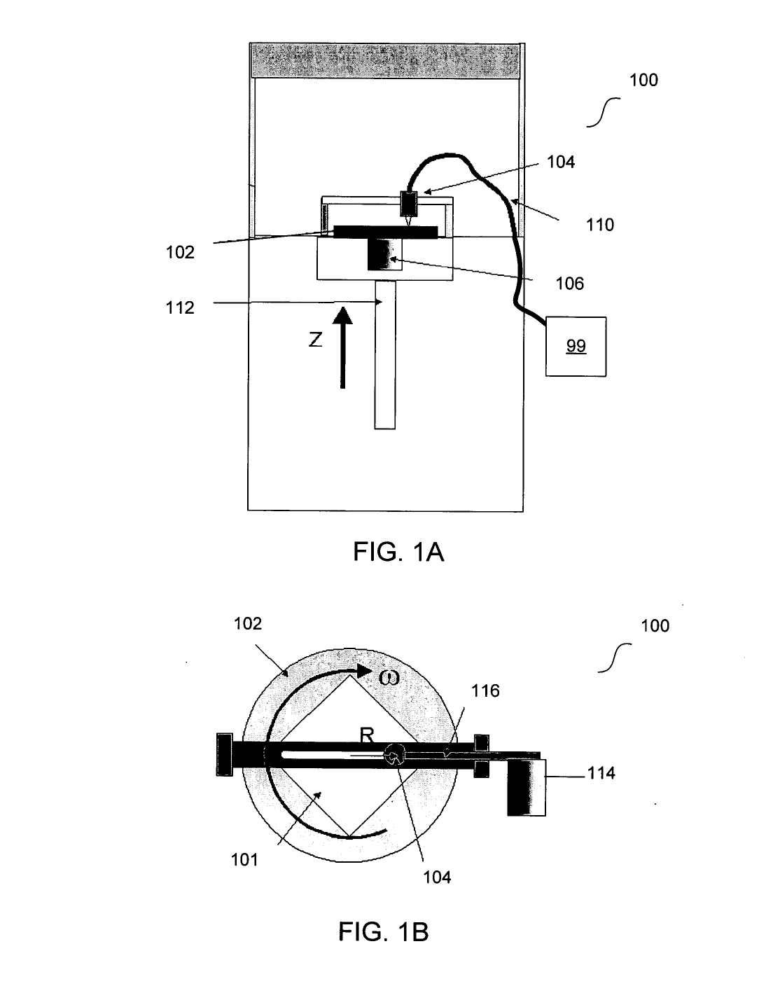

Referring to FIGS. 1A and 1B, a side-view and top-view of cleaning tool 100 according to embodiments of the invention are shown. Surface 101 comprising contaminate particles including, without limitation, dust, organic materials, metal impurities, and the like may be mounted on chuck 12 that can rotate around an z-axis via motor 106. In some embodiments, surface 101 may be a substrate. Alternatively, surface 101 may be a plate, silicon wafers (patterned and unpatterned), glass wafers (patterned and unpatterned), glass substrates, photomask substrates, masks, or any other surfaces that include contaminant particles. Coupled to chuck 102 may be nozzle 104 which may be mounted on an arm on the top of chuck 102. A light source 99, such as a laser coupled to nozzle 114, may be focused on surface 101 and used to remove particles. The light source may include, for example, may include, without limitation, high pressure mercury lamp (wavelength of about 250-450 nm), low pressure mercury lamp (wavelength of about 180-480 nm), UV light emitting and/or laser diode (wavelength of about 300-400 nm), metal halide lamp (wavelength of about 200-450 nm), Xe2 excimer lamp (wavelength of about 172 nm), Ar2 excimer lamp (wavelength of about 146 nm), KrCl excimer lamp (wavelength of about 222 nm), XeI excimer lamp (wavelength of about 254 nm), XeCl excimer lamp (wavelength of about 308 nm), ArF excimer laser (wavelength of about 193 nm), KrF excimer laser (wavelength of about 248 nm), F2 laser (wavelength of about 157 nm).

In some embodiments, nozzle 104 may move on a radial axis and may allow for full scanning of the surface of the substrate, using for example, nozzle motor 114. Alternatively or in addition, nozzle 104 may be coupled to nozzle arm 116 that may move nozzle 104 in, for example, a vertical and/or horizontal manner parallel to the surface. In addition to a scanning operation, nozzle arm 116 may be used for localized or targeted cleaning by moving the rotating the stage to an angle (θ) of and nozzle to location (r). Hence, if the defect location is known, the nozzle may be moved to the specific location and cleaning process applied to that point, and thus, limits and/or substantial eliminates damage to the surface.

In one embodiment, cleaning tool 100 may be used integrated in a dry cleaning tool for dry cleaning of a substrate. The application of a light source, such as, but not limited to a UV light source, may change the condition of most surfaces of interest to hydrophilic that leads to a lower number of particles both in spin drying and surface-tension-gradient based drying processes in cleaning tools. Alternatively, cleaning tool 100 may be integrated into a wet cleaning tool (e.g., stripping tools, etching tools, etc.) and may be used for cleaning of a substrate in combination with a wet cleaning process.

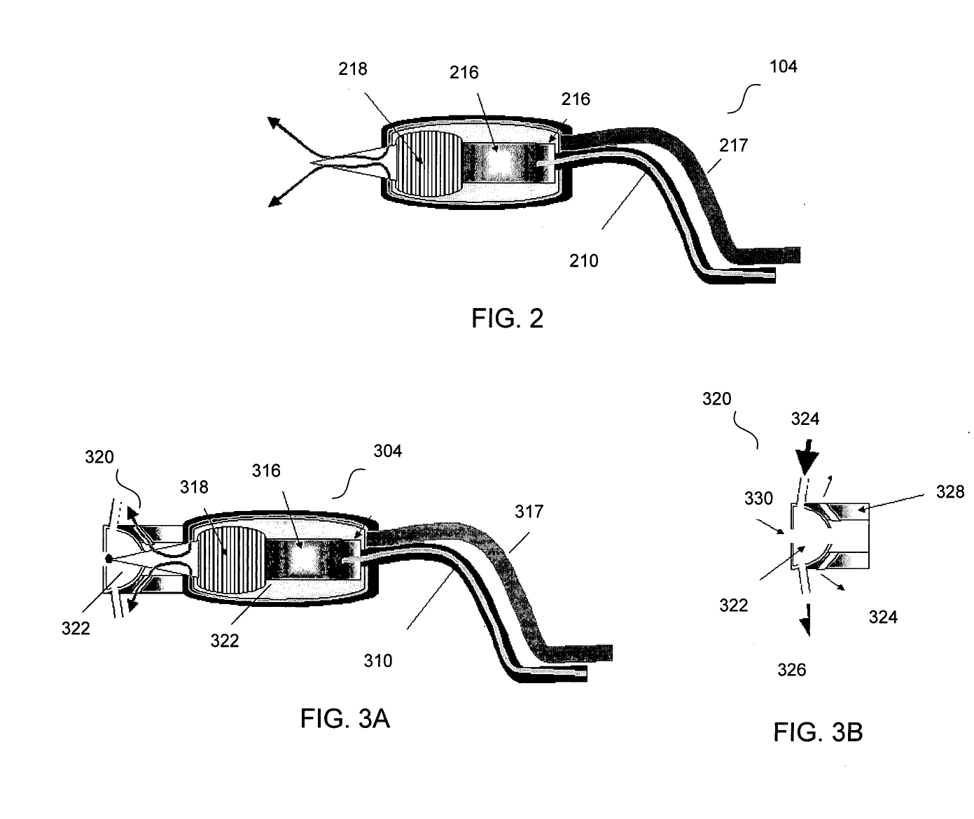

Referring to FIG. 2, a closer view of nozzle 104 is shown. Nozzle 104 may include optical fiber 210 that may be coupled to collimator 216 via fiber coupler 218, and provides light from a light source 99 to surface 101. It is noted that optical fiber 210 may be coupled to collimator 216 via other coupling means, including, without limitation, direct coupling or via a SubMiniature version A (SMA) connector. Alternatively, optical fiber 210 may be embedded into nozzle arm 216, which swivels, rotates, and/or slides over surface 101. In these configurations, the window of a light source may be heated by using heater or peltier device (not shown) to prevent liquid condensation on the window or mirror surface. Nozzle 104 may also include lens element 218 coupled to collimator 216 may be used for focusing the laser beam on the desired surface. In some embodiments, a lens element 218 may include one lens. Alternatively, lens element 218 may include a plurality of lenses.

Cleaning tool 100 may be covered by a housing (e.g., polyvinylidene fluoride, PVDF) that may include a gap. A gas, such as, but not limited to, highly purified nitrogen may flow through this gap through gas feed 217 into a front portion of a lens to protect lens 218 from chemicals during the cleaning operation. In one embodiment, the gas may prevent condensation on lens element 218. Alternatively, the flow of substantially pure nitrogen may also protect lens element 218 during the laser operation.

Nozzle 104 may provide a light source operating in different modes. In one embodiment, the light source may include a laser which may operate in a direct laser cleaner mode in which the laser light may be focused on the defect on the surface and the defect may be removed by expansion. This may be done by rotating nozzle 104 over about the area of the defect and allows a focused light spot onto a portion of the surface, such that the defects in the expose area may be removed. If the laser is focused on a few microns spot and if a particle is small (e.g., a few hundred nanometers), the damage area may be limited and/or substantially minute compared to conventional techniques. In another embodiment, if direct laser cleaning is used in combination with substrate scanning, the average energy applied to the surface may be lower and some degree of damage control is possible.

In another embodiment, nozzle 104 may allow the laser to remove particles in combination with a layer of liquid (e.g., water) provided onto surface 101. The focused laser at the surface may evaporate the liquid and cause fast movement of liquid parallel to the surface. This parallel flow may remove the particles from the surface.

Alternatively, if the wavelength of the laser is in the ultraviolet region, the photons may have enough energy to break the chemical bonds of the organic particles on the surface and may allow the particles to be easier to remove. In one embodiment, if oxygen is present in the environment, UV light can produce ozone, as described in U.S. Ser. No. ______, entitled “A Method and Apparatus for an In-Situ Ultraviolet Cleaning Tool,” filed on Dec. 13, 2005 and incorporated herein in its entirety. In turn, the produced ozone may react with the particles on the surface and subsequently remove them from the surface. Note that in this operation of the laser, the high intensity of the laser for ablation may not be used, but the high-energy photons may accelerate the desired chemical reactions by breaking unwanted chemical bonds.

If the wavelength of the laser is in the infrared or near-infrared region and the laser works in continuous operation mode or pulse operation mode with high pulse repetition rate, then the average energy transferred to the surface may be high enough to raise the temperature of the surface in the focal point of the laser light. The surface temperature may increase the chemical reactions that dissolve the particles. In another embodiment, if chemicals, such as dilute hydrofluoric acid are used, the surface may be etched. In some embodiments, the etching may be have an etch rate that depends on the temperature, which may rise at about or around the location of focused laser beam. It is noted that different chemicals and different particles may be used, as most chemical reactions are temperature dependent.

In other embodiments, a laser beam may be focused on a location above the surface such that if the laser intensity is above the breakdown field of the environment, plasma and a shock wave may be created. Referring to FIGS. 3A and 3B, plasma chamber cap 320 may be coupled to the laser nozzle 304 via fixture coupling 328 is shown. Plasma cap 320 may include chamber 322 where plasma may be formed. The gas pressure in chamber 322 may be controlled by flow of the gas and conductance of inlet 324, outlet 326, chamber 322, pinhole 330, incoming laser aperture, and the gas flow, such as nitrogen flow. Further, the temperature of the chamber may be controlled by an electric heater or heat exchange liquid heater (now shown for brevity).

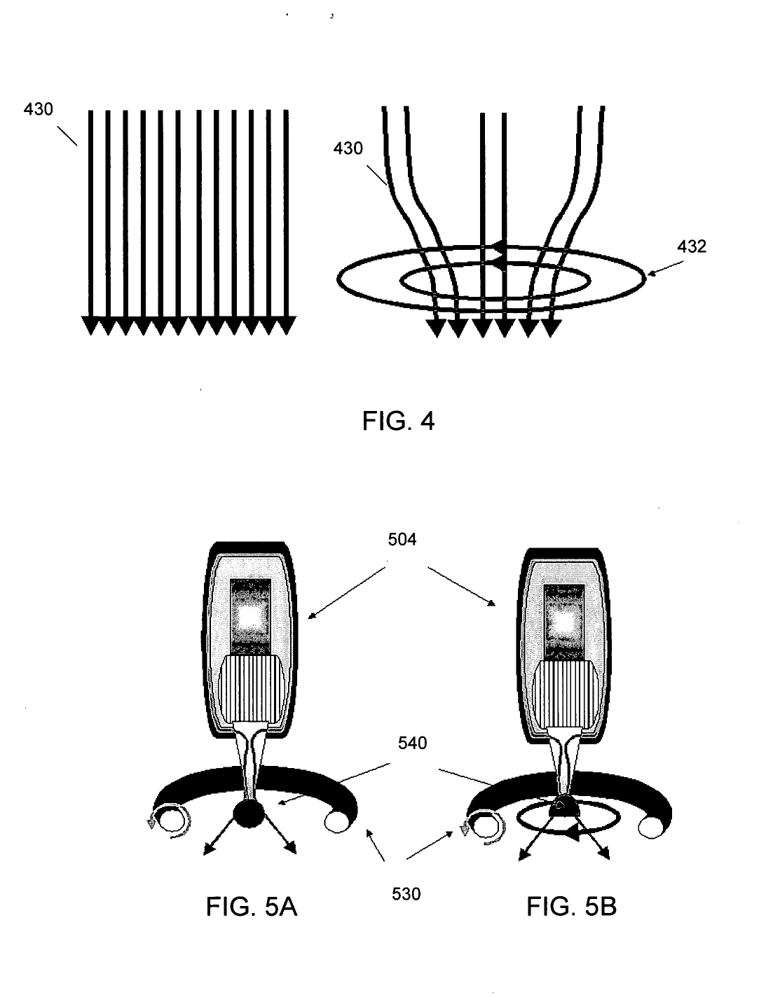

The plasma created in chamber 322 by a laser may disappear shortly after the laser intensity is reduced. As such, in one embodiment, the plasma may be contained by using a magnetic field 430 applied to the plasma in the direction shown in FIG. 4. The magnetic field lines may be created by moving charges in the plasma and confining these lines by applying magnetic field 432 normal to the direction of the magnetic field 430. After the creation of the plasma, charges may expand radially from the center of the plasma outwards.

In one embodiment, a torrid for creating an azimuth magnetic field may be used to confine the plasma. In FIG. 5A, plasma 540 may be created at the focal point inside torrid 530 absent magnetic field. Upon applying a magnetic field, plasma 540 may be confined in an upper part of torrid 530, as shown in FIG. 5B. In one embodiment, by adjusting the center of the magnetic field close enough to the focal point of the laser, plasma 540 may repel from the surface. Torrid 530 may have a dimension of few hundred microns, and thus, allows the whole assembly to be placed close to a surface (e.g., within about a few hundred microns). For example, in a typical laser shock wave setup, the focal point may be approximately 1.3 mm far from the surface.

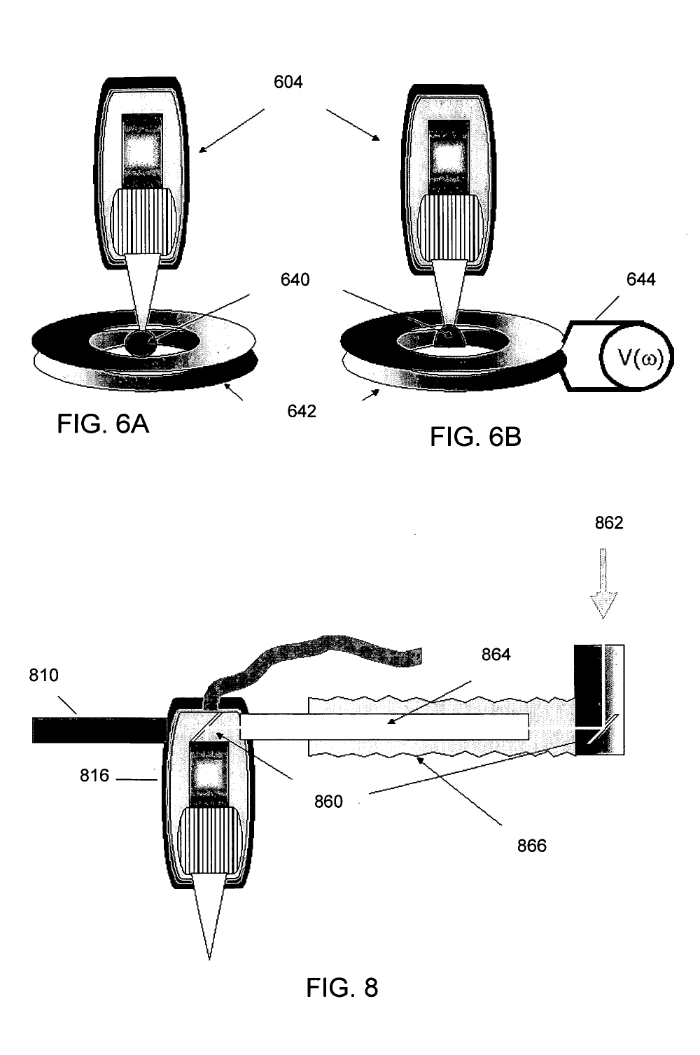

In other embodiments, plasma 640 may be confined by repelling the plasma within the two ring electrode configuration 642 when an electric field from electric power source 644 is applied, as shown in FIGS. 6A and 6B. In one embodiment, electric power source 644 may be a DC voltage that may impact the charge density in the plasma. For example, by applying a proper voltage of about 100V, the plasma may be repelled from the surface, as shown in FIG. 6B. In an alternative embodiment, electric power source 644 may be an AC field or radio frequency (RF) field that may be applied to the electrodes.

In some embodiments, plasma confinement may be done in the horizontal configuration with the methods described above but changing the electrode configuration. For example in the case that shown in FIG. 6, rectangular electrodes with a slit cut in the lower electrode may be used to allow the shock wave to propagate towards the surface of the plate, where the length of electrodes is more than the scanning distance of the laser. The laser light may enter horizontally between the two electrodes.

The creation of the shock wave may depend on the environment properties. For example, in a gas environment, the shock wave properties may depend, among other things, to gas pressure, temperature and composition. This shock wave may propagate through the media at a high velocity (approximately a few hundred meters per second or more) where the laser strikes the surface and may transfer high momentum to the particles on the surface to separate the particles from the surface. The surface damage may be controlled by limiting the intensity of the laser light and based on the distance between laser light and the surface. In addition to dry cleaning by shock wave, liquid-assisted shock cleaning may be used. The application of the shock to the surface with a thin liquid film may evaporate the liquid film and cause fast movement of liquid parallel to the surface. This parallel flow may remove the particles from the surface.

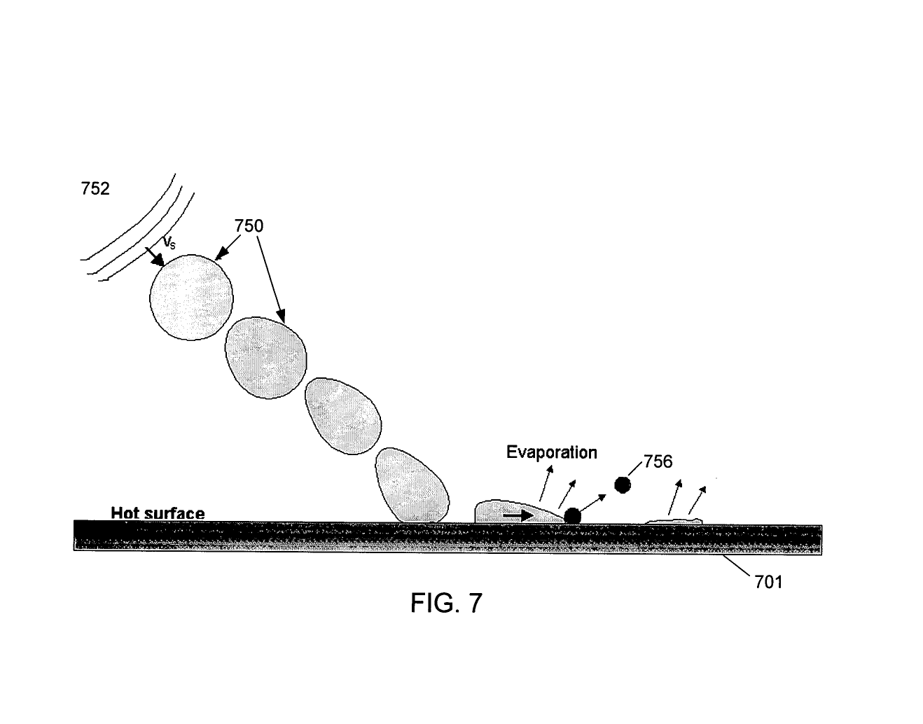

In one embodiment, a low-pressure vapor/fume may be created on the top of the surface, as shown in FIG. 7. This low-pressure vapor/fume may include droplets 750, such as microscale to nanoscale droplets, that may suspend above surface 701 such that when a shockwave is created in this surrounding; the shockwave may accelerate the droplets towards surface 701, where the speed of the droplet depends on the size of the droplets. In one embodiment, the shock wave may be created by discharge or arch methods. Other methods for creating shock waves may also be applicable. When droplets 750 hit surface 701, particles 756 may be disturbed and subsequently removed.

In other embodiments, the temperature at surface 701 may be at a range of about 30 to 90° C. such that substantially little or no condensation occurs at the surface. As such, droplets 750 may decrease in volume as they approach surface 701 and subsequently be evaporated.

As noted above, optical fibers (e.g., 110, 210, and 310 of FIGS. 1, 2, and 3, respectively) may be used for coupling the laser light to the nozzle and also may be used for different laser cleaning mode. However, during the creation of the shock wave, the order of energy may be greater than 50 mJ/cm². Although the available fibers can handle average power up to 10 watts, spontaneous power consumption is in the order of megawatts which may not be handled by normal optical fibers. As such, a direct coupling mechanism may be used for coupling the laser light to the nozzle. This design relies on single dimensional movement of a coupling arm. Referring to FIG. 8, an embodiment of the direct coupling is shown. Two parallel mirrors 860 may be used to direct light 862 from light source 99 into the nozzle. In one embodiment, one mirror of parallel mirrors 860 may be positioned on a top surface of collimator 816 at an angle of approximately about 45 degree with respect to the incoming light beam 862. Coupling arm 864, which directs incoming beam 862 to the mirror coupled to collimator 816, may be a hollow cylinder that may be fixed at one end to the nozzle and the other end may slide into the flexible arm. Coupling arm 864 may include protection sleeve 866 used to protect coupling arm 864 during the cleaning process and/or chemical exposure. Protection sleeve 866 may include, without limitation, a flexible jacket, bellow, or telescopic sleeve.

In some embodiments, collimator 816 may be coupled to nozzle arm 810 for moving the nozzle to a location on a surface that requires cleaning. As such, nozzle arm 810 may be coupled to the nozzle motor 114 as is shown in FIG. 1. Alternatively, nozzle arm 810 may be coupled to other mechanisms known in the art for rotating, sliding, and two-dimensional moving of the nozzle 804. Note that the arm movement is in the direction of the beam and therefore, the laser beam may pass through the arm and get focused on the surface, independent of the nozzle location.

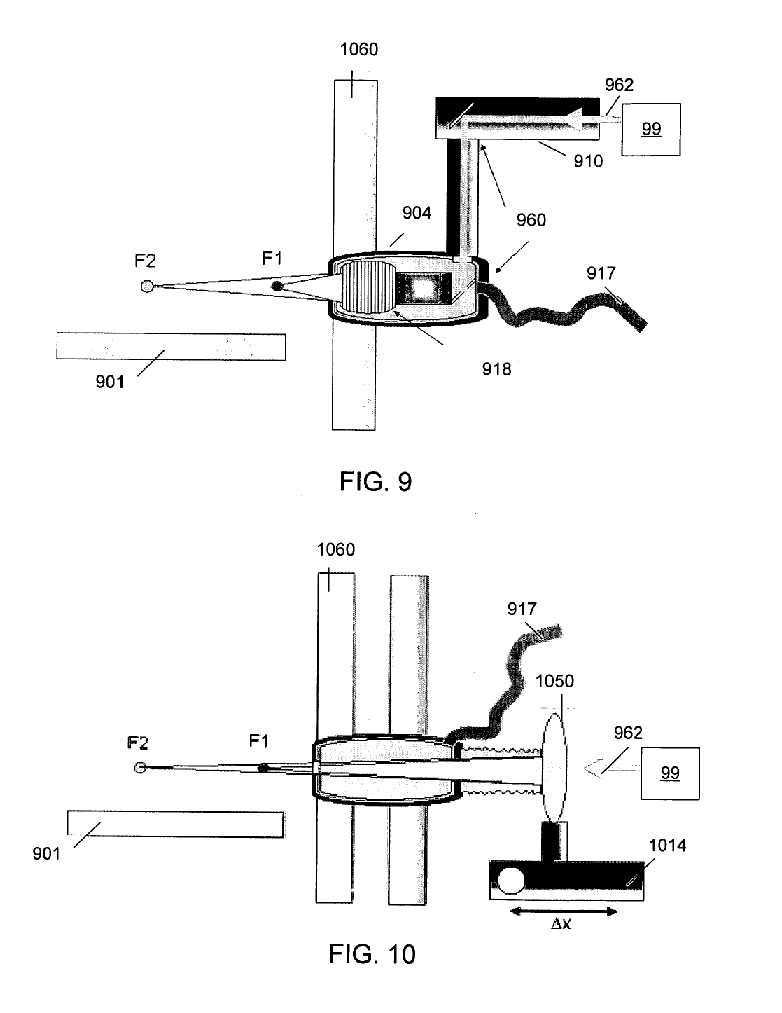

In a vertical configuration for the shock creation, if there is no plasma formation, the laser can directly hit the surface and may cause damage. Therefore, surface damage is one important issue in vertical configuration in which laser incidents normal to the plate surface. In order to avoid surface damage due to the direct exposure to surface from the laser beam, the laser light may be placed inside a cleaning tool substantially parallel to the surface of the plate. Incoming light 962 from light source 99 may be directed to surface 901 via nozzle arm 910 and a set of mirrors 960 spaced apart from each other. Nozzle 904 may remain fixed with respect to surface 104 to bowl wall 960 of a cleaning tool and the focal point (F1 and F2) may be shifted by using a motorized zoom from lens 918, as shown in FIG. 9. The focal point may range to different areas of surface 101, allowing a light to be used for particle removal.

Alternatively, the focal point may be scanned by moving a lens out of the process chamber into the optical setup as shown in FIG. 10, where nozzle 1004 may remain fix to bowl wall 1060 relative to surface 101. Here, incoming light 1062 from light source 99 may be directed to a surface via moving lens 1050 coupled to a means for rotating the moving lens in a range of about Δx. Δx is change from one focal point to another focal point (e.g., F1 to F2, or F2 to F1) covers the area of surface 1001. The means for rotating moving lens may include motor 1014. Alternatively, other means for rotating moving lens known in the art may be applicable. By rotating moving lens 1050, the focal points (e.g., F1 and F2) may change relative to surface 1001.

The present disclosure provides targeted cleaning of a surface (e.g., mask and/or wafer) where the surface may first by inspected by a defect inspection tool. Next, the hard or soft defects are determined and the cleaning techniques mentioned above are used to locally remove the particles by targeting specific location of the defect on the surface. In this approach hard defects are removed locally.

The techniques that described above may be used for defect removal of both mask and wafers and other surfaces of interests. Further the techniques may be integrated to cleaning tools. Further, the present disclosure offers designs and concepts that can lead to a standalone laser based cleaning tool or as an added module to an existing cleaning tool.

All of the apparatuses disclosed and claimed herein can be made and executed without undue experimentation in light of the present disclosure. While the apparatus and methods of this invention have been described in terms of preferred embodiments, it will be apparent to those of skill in the art that variations may be applied to the methods and in the steps or in the sequence of steps of the method described herein without departing from the concept, spirit and scope of the invention. In addition, modifications may be made to the disclosed apparatus and components may be eliminated or substituted for the components described herein where the same or similar results would be achieved. All such similar substitutes and modifications apparent to those skilled in the art are deemed to be within the spirit, scope, and concept of the invention as defined by the appended claims.

1. An apparatus for removing a contaminant particle from a surface, comprising:
a surface having contaminant particles thereon;
a light source; and
a nozzle coupled to the light source, the nozzle operably moveable to a location on the surface having the particles and providing light from the light source operating in a plurality of modes to remove the contaminant particles by expansion.

2. The apparatus of claim 1, the light source operating in a direct cleaning mode comprising an ultraviolet wavelength.

3. The apparatus of claim 2, the ultraviolet wavelength creating ozone between the light source and the surface, the ozone breaking the chemical bond between the contaminant particle and the surface.

4. The apparatus of claim 1, the light source operating in a direct cleaning mode comprising an infrared wavelength.

5. The apparatus of claim 4, the infrared wavelength increasing a temperature at and around the contaminant particles on the surface, the increased temperature accelerating chemical reactions for dissolving the contaminant particles.

6. The apparatus of claim 1, further comprising a liquid layer on the surface, the light source evaporating the liquid layer to remove the particles.

7. The apparatus of claim 1, the light source creating a shockwave for producing droplets, the droplets removing the contaminant particles on the surface.

8. The apparatus of claim 1 being integrated into a wet processing chamber.

9. The apparatus of claim 8, further comprising a lens element coupled to the nozzle.

10. The apparatus of claim 8, the light source being selected from the group consisting of a high pressure mercury lamp, a low pressure mercury lamp, an ultraviolet light emitting diode, an ultraviolet laser diode, a metal halide lamp, a Xe2 excimer lamp, a KrCl excimer lamp, a XeI excimer lamp, a XeCl excimer lamp, an ArF excimer laser, a KrF excimer laser, an Ar2 excimer lamp, and a F2 laser.

11. The apparatus of claim 8, further comprising a plasma cap coupled to the nozzle for creating plasma under different gas flow parameters.

12. The apparatus of claim 12 claim 8, further comprising a torriod for applying a magnetic field around the plasma to confine the plasma over the surface

13. The apparatus of claim 12 claim 8, further comprising electrodes for applying an electric field around the plasma to confine the plasma over the surface.
